(19) United States
(12) Patent Application Publication
(10) Pub. No.: US 2025/0236987 A1
(43) Pub. Date: Jul. 24, 2025

(54) SILICON CARBIDE AND QUARTZ COMPOSITIONS FOR PROCESSING CHAMBERS, AND RELATED COMPONENTS AND METHODS

(71) Applicant: Applied Materials, Inc., Santa Clara, CA (US)

(72) Inventors: Kim Ramkumar VELLORE, San Jose, CA (US); Zhepeng CONG, San Jose, CA (US)

(21) Appl. No.: 18/581,127

(22) Filed: Feb. 19, 2024

Related U.S. Application Data
(60) Provisional application No. 63/624,068, filed on Jan. 23, 2024.

(51) Int. Cl. C30B 25/10; C03C 14/00; C23C 16/458; C23C 16/46; C30B 25/12

(52) U.S. Cl. CPC C30B 25/10; C03C 14/004; C23C 16/4585; C23C 16/46; C30B 25/12; C03C 2214/04

(57) ABSTRACT

Embodiments of the present disclosure generally relate to compositions for use in a substrate processing chamber, and related methods. In one or more embodiments, a component includes a body having a composition. The composition comprising a mixture of silicon carbide (SiC) particles suspended in quartz.

### CROSS-REFERENCE TO RELATED APPLICATION

This application claims priority to U.S. Provisional Patent Application No. 63/624,068, filed Jan. 23, 2024, which is herein incorporated by reference in its entirety.

### BACKGROUND

### Field

Embodiments of the present disclosure generally relate to a composition for use in a substrate processing chamber, and related methods.

### Description of the Related Art

Continuous reduction in size of semiconductor devices is dependent upon more precise control of, for instance, the flow and temperature of process gases delivered to a semiconductor process chamber. Typically, in a cross-flow chamber, a process gas may be delivered to the chamber and directed across the surface of a substrate to be processed. The temperature of the process gas may be affected by, for example a pre-heat ring.

Pre-heat rings as well as other components within a processing chamber have limitations with respect to heating and processing. For example, components that can quickly heat up also can cool down quickly between processing cycles, which can cause heating inefficiencies and increased power consumption. As another example, more pronounced temperature differentials throughout power cycles can cause increased fatigue of the components, which can cause fractures (e.g., cracks) in the components.

Therefore, a need exists for improved composition and/or methods to form components within a processing chamber.

### SUMMARY

Embodiments of the present disclosure generally relate to a composition for use in a substrate processing chamber, and related methods.

In one or more embodiments a component includes a body having a composition. The composition comprising a mixture of silicon carbide (SiC) particles suspended in quartz.

In one or more embodiments a processing chamber applicable for use in semiconductor manufacturing includes a chamber body and a window. The chamber body and the window at least partially define a processing volume. The processing chamber further includes a plurality of heat sources is configured to heat the processing volume and a substrate support disposed in the processing volume. The processing chamber further includes a liner configured to at least partially line the chamber body and a pre-heat ring disposed in the processing chamber and at least partially supported by the liner. The pre-heat ring includes a body having a composition. The composition includes a mixture of silicon carbide (SiC) particles suspended in quartz.

In one or more embodiments, a method of forming a composition includes immersing silicon carbide (SiC) powder in liquid quartz, mixing the silicon carbide and liquid quartz into a SiC quartz mixture, and curing the SiC quartz mixture.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial schematic side cross-sectional view of a processing chamber, according to one or more embodiments.

FIG. 2 is a schematic axonometric view of the pre-heat ring shown in FIG. 1, according to one or more embodiments.

FIG. 3 is a schematic top view of the pre-heat ring shown in FIG. 1, according to one or more embodiments.

FIG. 4 is a schematic axonometric view of a pre-heat ring, according to one or more embodiments.

FIG. 5 is a schematic top view of the pre-heat ring shown in FIG. 4, according to one or more embodiments.

FIG. 6 is a schematic axonometric view of a pre-heat ring, according to one or more embodiments.

FIG. 7 is a schematic top view of the pre-heat ring shown in FIG. 6, according to one or more embodiments.

FIG. 8 is a schematic block diagram view of a method of substrate processing for semiconductor manufacturing, according to one or more embodiments.

FIG. 9 is a schematic block diagram view of a method of forming a composition, according to one or more embodiments.

FIG. 10 is a graphical representation of the transmissivity of a 4H-SiC quartz mixture composition compared to the transmissivity of a SiC substrate at various electromagnetic wavelengths, according to one or more embodiments.

FIG. 11 is a graphical representation showing two profiles according to one or more embodiments.

FIG. 12 is a graphical representation showing two profiles according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to semiconductor processing chambers, and more particularly, compositions to form different components within the processing chambers.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

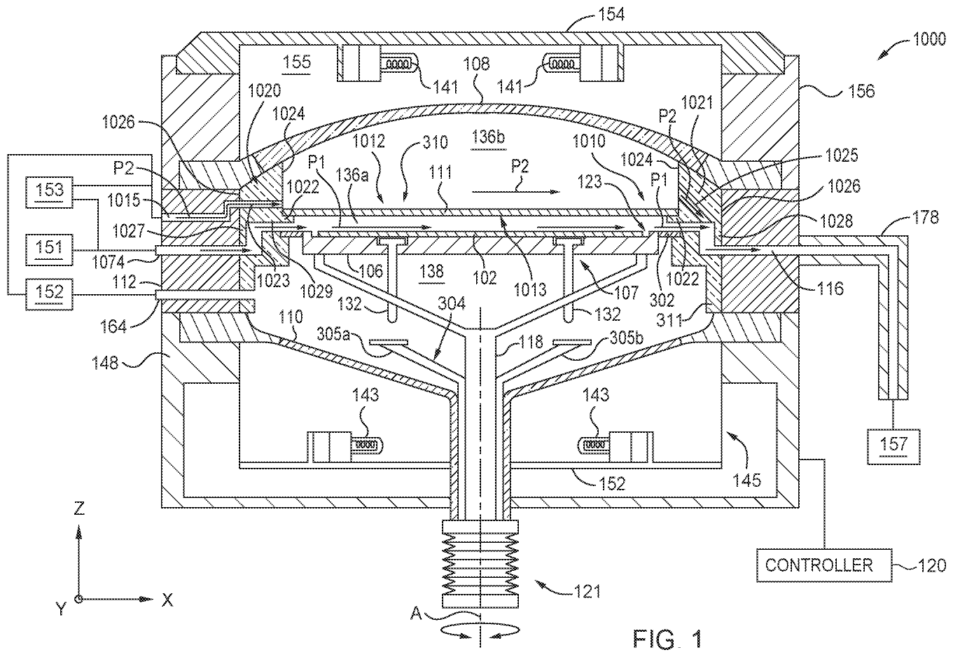

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper window 108 and the lower window 110. The substrate support 106 includes a support face 123 that supports the substrate 102. The plurality of upper heat sources 141 are disposed between the upper window and a lid 154. The plurality of upper heat sources 141 form a portion of the upper heat source module 155. The lid 154 may include a plurality of sensors (not shown) disposed therein or thereon for measuring the temperature within the processing chamber 100. The plurality of lower heat sources 143 are disposed between the lower window 110 and a floor 152. The plurality of lower heat sources 143 form a portion of a lower heat source module 145. In one or more embodiments, the upper window 108 is an upper dome and is formed of an energy transmissive material, such as quartz. In one or more embodiments, the lower window 110 is a lower dome and is formed of an energy transmissive material, such as quartz. A pre-heat ring 302 is disposed outwardly of the substrate support 106. The pre-heat ring 302 is supported on a ledge of the lower liner 311. The pre-heat ring 302 has a curved body and a central opening. A stop 304 includes a plurality of arms 305a, 305b that each include a lift pin stop on which at least one of the lift pins 132 can rest when the substrate support 106 is lowered (e.g., lowered from a process position to a transfer position).

The pre-heat ring 302 is formed of a composition which includes silicon carbide (SiC) particles suspended in quartz. For example, the SiC particles can be SiC powder suspended in liquid quartz to form the composition. In one or more embodiments, the composition formed is a homogenous mixture. A size of the SiC powder particles can be used to achieve the homogenous mixture. The composition of the pre-heat ring 302 includes a mixture of transparent quartz with SiC particles suspended within the transparent quartz. The mixture of the composition can be translucent. A concentration of the SiC particles in the composition is greater than 1% and less than 5% by volume of the composition (e.g., the SiC quartz mixture). In one or more embodiments the composition (e.g., the SiC quartz mixture) includes a concentration of 2%-3% of SiC particles. In one or more embodiments the SiC particles are amorphous, such as lattice type amorphous SiC particles. In one or more embodiments the SiC particles have an atomic structure of 4H. In one or more embodiments the SiC particles have an atomic structure of 6H. In one or more embodiments the SiC particles have a crystalline structure. The composition (e.g., the SiC quartz mixture) can be transparent for visible light in the visible wavelength range (e.g., light having a wavelength of 2.7 microns or 3.3 microns). The composition is also opaque (such as about 100% opaque) for other light(s) such as for infrared light in the infrared wavelength range (e.g., light having a wavelength within a range of 1 micron to 2 microns, or light having a wavelength within a range of 900 nm to 1700 nm) and/or ultraviolet light in the ultraviolet wavelength range (e.g., light having a wavelength less than 500 nm). The composition can remain opaque for the other light(s) at processing temperatures below 600 degrees Celsius. The composition facilitates relatively hot surfaces (e.g., for process gas activation) of the pre-heat ring 302 at relatively low heating powers.

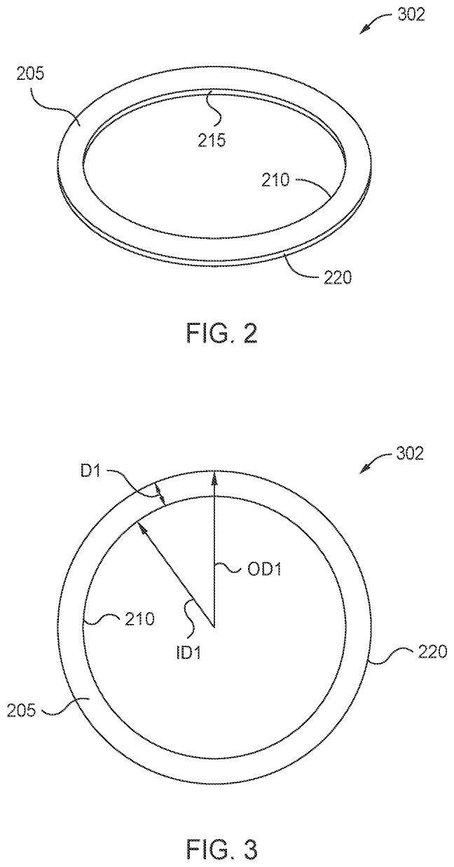

The pre-heat ring 302 composition allows for visible light to pass through the pre-heat ring 302, but infrared (IR) wavelengths are absorbed by SiC quartz mixture that makes up the pre-heat ring 302. FIGS. 2-7 depict a pre-heat ring 302 formed from this SiC quartz mixture, however it should be understood that other components for disposition in the processing chamber 1000 such as the lower liner 311, the upper liner 1020, and/or the substrate support 106 can be formed out of the same composition including the SiC quartz mixture as the pre-heat ring 302.

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

A process kit 1010 includes an isolation plate 111 having a first outer face 1012 and a second outer face 1013 opposing the first outer face 1012. The second outer face 1013 faces the substrate support 106. The process kit 1010 includes an upper liner 1020. The upper liner 1020 includes an annular section 1021. The upper liner 1020 includes one or more inlet openings 1023 extending to an inner surface 1024 of the annular section 1021 on a first side of the upper liner 1020, and one or more outlet openings 1025 extending to the inner surface 1024 of the annular section 1021 on a second side of the upper liner 1020.

The one or more inlet openings 1023 extend from an outer surface 1026 of the annular section 1021 of the upper liner 1020 to the inner surface 1024. The one or more outlet openings 1025 extend from a lower surface 1029 of the upper liner 1020 to the inner surface 1024. The upper liner 1020 includes a first extension 1027 and a second extension 1028 disposed outwardly of the lower surface 1029 of the upper liner 1020. At least part of the annular section 1021 of the upper liner 1020 is aligned with the first extension 1027 and the second extension 1028. In the embodiment shown in FIG. 1, a lowermost end of the isolation plate 111 is aligned above a lowermost end of the upper liner 1020. In one or more embodiments, as shown in FIG. 1, the lowermost end of the isolation plate 111 is part of the second outer face 1013, and the lowermost end of the upper liner 1020 is part of the first extension 1027 and/or the second extension 1028. The present disclosure contemplates that the lowermost end of the upper liner 1020 can be part of the lower surface 1029.

The isolation plate 111 is in the shape of a disc, and the annular section 1021 is in the shape of a ring. It is contemplated, however, that the isolation plate 111 and/or the annular section 1021 can be in the shape of a rectangle, or other geometric shapes. The isolation plate 111 at least partially fluidly isolates the upper portion 136b from the lower portion 136a. The present disclosure contemplates that the isolation plate 111 can be omitted.

The flow module 112 (which can define at least part of one or more sidewalls of the processing chamber 1000) includes one or more first inlet openings 1014 in fluid communication with the lower portion 136a of the processing volume 136. The flow module 112 includes one or more second inlet openings 1015 in fluid communication with the upper portion 136b of the processing volume 136. The one or more first inlet openings 1014 are in fluid communication with one or more flow gaps between the upper liner 1020 and the lower liner 311. The one or more second inlet openings 1015 are in fluid communication with the one or more inlet openings 1023 of the upper liner 1020. The first inlet openings 1014 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one embodiment, which can be combined with other embodiments, the one or more process gases include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

In one or more embodiments, as shown in FIG. 1, the one or more inlet openings 1023 are oriented in a horizontal orientation and the one or more outlet openings 1025 are oriented in an angled orientation. The present disclosure contemplates that the one or more inlet and/or outlet openings 1023, 1025 can be oriented in a horizontal orientation, oriented in an angled (e.g., non-parallel to horizontal) orientation, and/or can include one or more turns (such as the turns shown for the one or more first inlet openings 1014 and the one or more gas exhaust outlets 116).

During a deposition operation (e.g., an epitaxial growth operation), the one or more process gases P1 flow through the one or more first inlet openings 1014, through the one or more gaps, and into the lower portion 136a of the processing volume 136 to flow over the substrate 102. During the deposition operation, one or more purge gases P2 flow through the one or more second inlet openings 1015, through the one or more inlet openings 1023 of the upper liner 1020, and into the upper portion 136b of the processing volume 136. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 1020 and the lower liner 311, and through the one or more gas exhaust outlets 116. The one or more purge gases P2 are exhausted through the one or more outlet openings 1025, through the same gaps between the upper liner 1020 and the lower liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that one or more purge gases can be supplied to the purge volume 138 (through the plurality of purge gas inlets 164) during the deposition operation, and exhausted from the purge volume 138.

FIG. 2 is a schematic axonometric view of the pre-heat ring 302 shown in FIG. 1, according to one or more embodiments.

FIG. 3 is a schematic top view of the pre-heat ring 302 shown in FIG. 1, according to one or more embodiments.

The pre-heat ring 302 includes one or more ring segments. In one or more embodiments (and as shown in FIGS. 2 and 3), the pre-heat ring 302 includes one complete ring in the form of a complete circle. The pre-heat ring 302 has an inner edge 210 that defines an inner dimension ID1. The pre-heat ring 302 has an outer edge 220 that defines an outer dimension OD1. In one or more embodiments, the inner dimension ID1 is an inner radius and the outer dimension OD1 is an outer radius. In one or more embodiments, the outer dimension OD1 is a major dimension of the pre-heat ring 302 and the inner dimension ID1 is a minor dimension of the pre-heat ring 302. A first side surface 205 is between the inner edge 210 and the outer edge 220. A second side surface 215 is between the inner edge 210 and the outer edge 220. In one or more embodiments, the first side surface 205 is part of a flat face of the pre-heat ring 302, and the second side surface 215 is part of an L-shaped face of the pre-heat ring 302.

A distance D1 is between the inner dimension and the outer dimension. The distance D1 is less than or equal to 40 mm. In one or more embodiments, the distance D1 is within a range of 20 mm to 40 mm, such as 30 mm to 35 mm, such as 33 mm. The distance D1 is a distance ratio of the inner dimension ID1. The distance ratio is less than or equal to 0.25. In one or more embodiments, the distance ratio is within a range of 0.15 to 0.25, such as within a range of 0.17 to 0.19. In one or more embodiments, the distance ratio is about 0.18.

As discussed above, the pre-heat ring 302 includes the SiC quartz mixture. The SiC quartz mixture includes silicon carbide (SiC) particles (e.g., powder) suspended in liquid quartz.

The SiC quartz mixture has a composition including a volume percentage of the SiC particles that is greater than or equal to 1.0% and less than or equal to 5.0%. In one or more embodiments, the SiC volume percentage is within a range of 2% to 3%. The amount of SiC particles and position of SiC particles can be tuned for different applications, IR absorption as well as visible light transmissivity can be adjusted by using different amounts of SiC particles. Different types of SiC particles can be used depending on the application such as powdered polymorphous SiC (e.g., 4H-SiC or 6H-SiC).

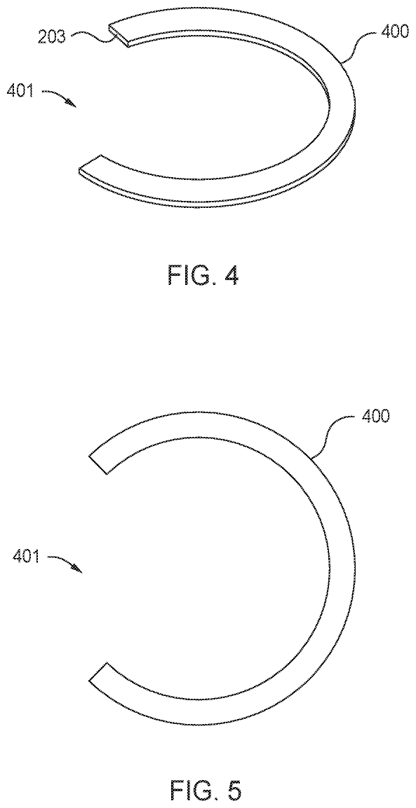

FIG. 4 is a schematic axonometric view of a pre-heat ring 400, according to one or more embodiments.

FIG. 5 is a schematic top view of the pre-heat ring 400 shown in FIG. 4, according to one or more embodiments.

The pre-heat ring 400 is similar to the pre-heat ring 302 shown in FIG. 2, and includes one or more of the aspects, features, components, properties, and/or operations thereof. The pre-heat ring 400 can be used in place of the pre-heat ring 302 in FIG. 1. The pre-heat ring 400 is a C-ring that includes one ring segment in the shape of a “C” and has a gap 401.

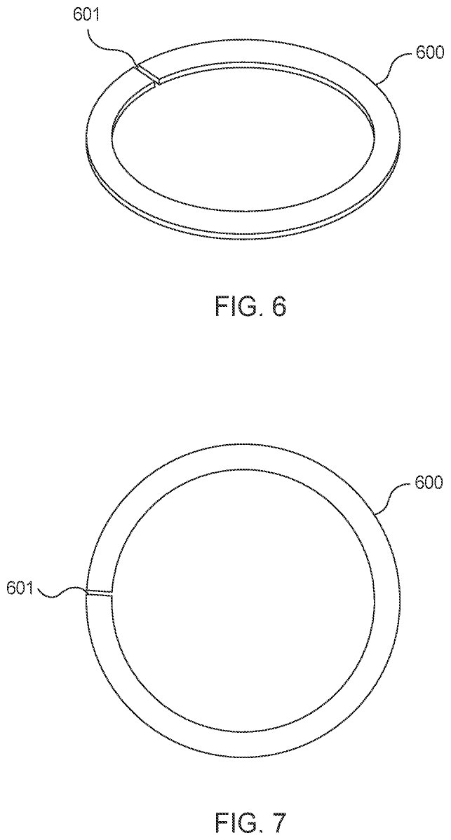

FIG. 6 is a schematic axonometric view of a pre-heat ring 600, according to one or more embodiments.

FIG. 7 is a schematic top view of the pre-heat ring 600 shown in FIG. 6, according to one or more embodiments.

The notched pre-heat ring 600 is similar to the pre-heat ring 302 shown in FIG. 2, and includes one or more of the aspects, features, components, properties, and/or operations thereof. The pre-heat ring 600 can be used in place of the pre-heat ring 302 in FIG. 1. The pre-heat ring 600 includes one ring segment that has a notch defining a gap 601.

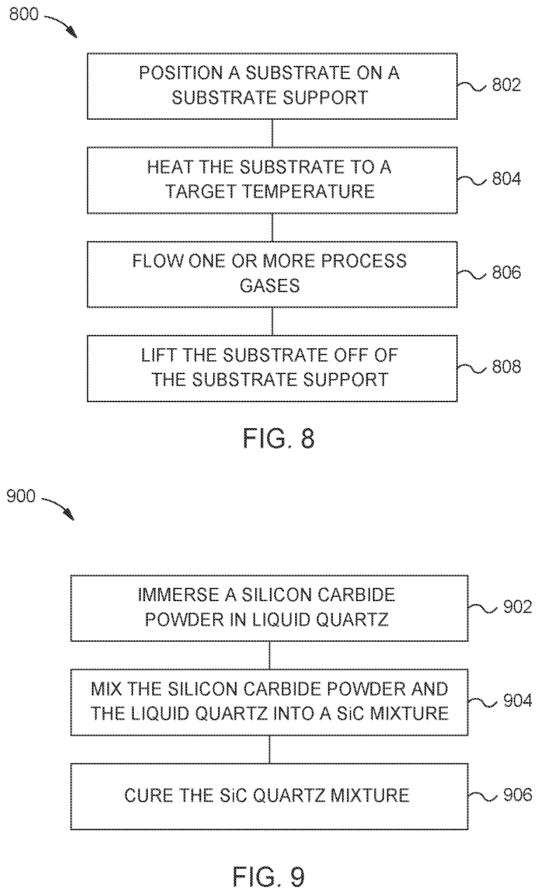

FIG. 8 is a schematic block diagram view of a method 800 of substrate processing for semiconductor manufacturing, according to one or more embodiments.

Operation 802 includes positioning a substrate on a substrate support in a processing volume of a processing chamber. In one or more embodiments, the positioning includes moving a substrate support and/or a plurality of lift pins relative to each other to land the substrate on the substrate support.

Operation 804 of the method 800 includes heating the substrate to a target temperature.

Operation 806 includes flowing one or more process gases over the substrate to form one or more layers on the substrate.

Operation 808 includes lifting the substrate off of the substrate support. In one or more embodiments, the lifting includes moving a substrate support and/or a plurality of lift pins relative to each other to engage the substrate with the lift pins and lift the substrate.

FIG. 9 is a schematic block diagram view of a method 900 of forming a composition, according to one or more embodiments.

Operation 902 includes immersing silicon carbide powder into liquid quartz. In one or more embodiments the SiC powder has an atomic structure of 4H. In one or more embodiments the SiC powder has an atomic structure of 6H. In one or more embodiments the SiC powder is crystalline. In one or more embodiments the liquid quartz is transparent in visible light.

Operation 904 includes mixing the SiC powder and the liquid quartz into a SiC quartz mixture.

Operation 906 includes curing the SiC quartz mixture. The SiC mixture can be cured with heat, radiation, UV light, electron beams, and/or chemical additives. The SiC quartz mixture can be cured or hardened into different geometric shapes as needed. For example, the SiC mixture can be cured to form the pre-heat ring 302, the lower liner 311, the upper liner 1020, and/or the substrate support 106.

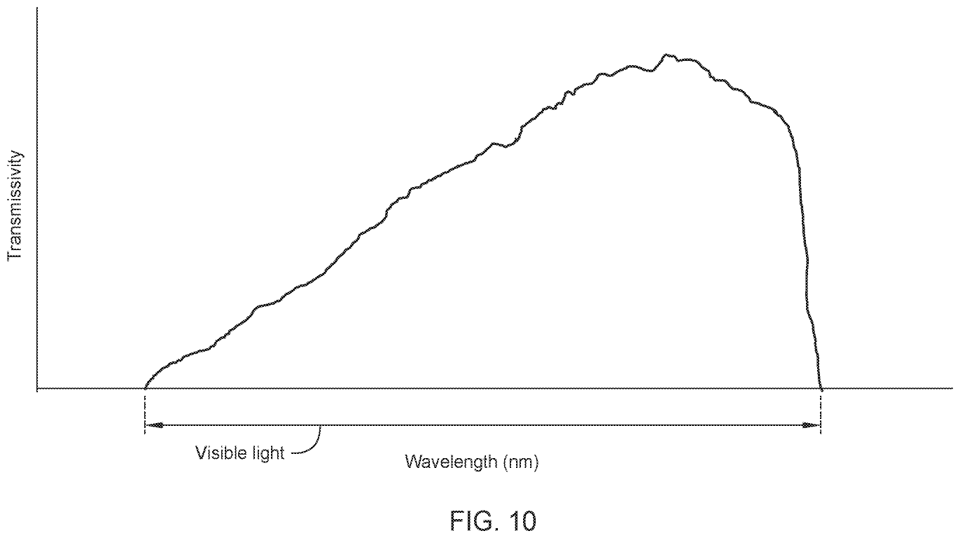

FIG. 10 is a graphical representation of the transmissivity of a 4H-SiC quartz mixture composition at various electromagnetic wavelengths, according to one or more embodiments.

At lower wavelengths and higher wavelengths outside of the visible light range the 4H-SiC quartz mixture absorbs almost all of the energy. Within the visible range, the 4H SiC quartz mixture allows at least some of the light to pass through.

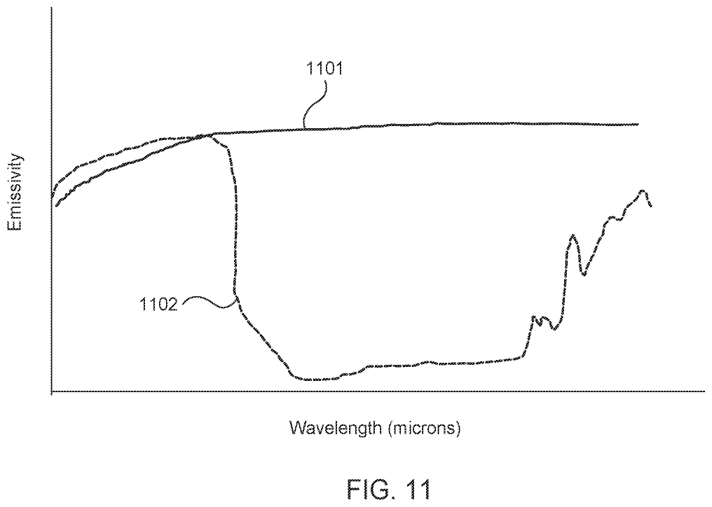

FIG. 11 is a graphical representation showing two profiles 1101, 1102, according to one or more embodiments.

A first profile 1101 shows the emissivity of a material at a first temperature. A second profile 1102 shows the emissivity of the material at a second temperature that is lower than the first temperature. As shown across a variety of wavelengths, a variety of emissivities can be achieved for the material by using different processing temperatures.

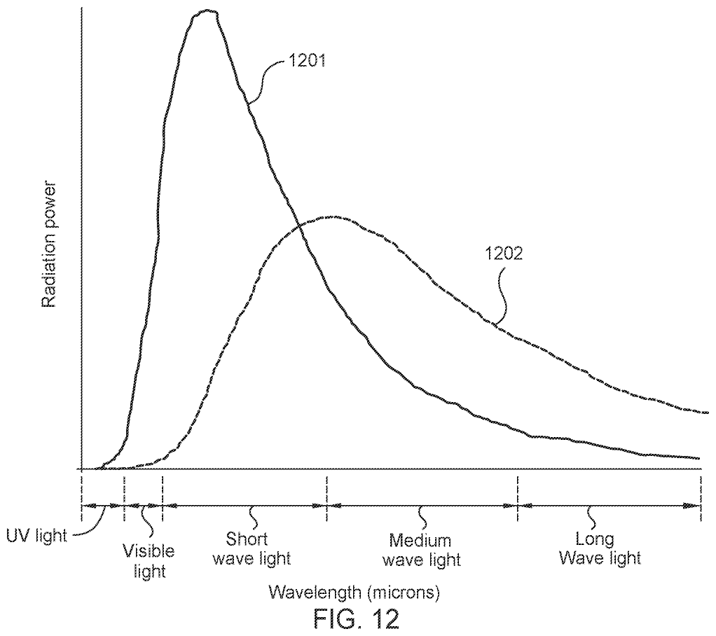

FIG. 12 is a graphical representation showing two profiles 1201, 1202, according to one or more embodiments.

A first profile 1201 shows the radiation of a first heat source operating at a first temperature. A second profile 1102 shows the radiation power of a second heat source operating at a second temperature that is lower than the first temperature. As shown across a variety of wavelengths, the radiation power of a heat source can shift based at least on the wavelength of light emitted. Hence, it can be difficult to adjust the processing temperature of a component using a heat source. For example, it can be difficult to adjust the processing temperature of a component without altering the amount of light that is absorbed and/or transmitted by the component. As shown in FIG. 12 and by using the subject matter described herein, more light outside of the visible wavelength range can be absorbed for hotter component surfaces at relatively lower processing temperatures.

Benefits of the present disclosure include reduced diversive flow of process gases; enhanced deposition thicknesses; enhanced deposition uniformities; more laminar gas flow (e.g., reduced or eliminated vortex effects of substrate rotation); reduced cost of manufacturing; enhanced thermal uniformities; enhanced gas flow rate uniformities; and increased throughput and efficiency; and reduced chamber downtime. Benefits of the present disclosure also include enhanced gas activation (e.g., pre-activation) while reducing or eliminating blockage of radiation that heats the substrate; increased film thickness and growth rates; and adjustability of process parameters (e.g., gas flow rates, temperature, and deposition thickness). As an example, the subject matter described herein can be used to adjust a transparency-relative-to-absorption factor for heating paths to facilitate a reduced or eliminated shadowing effect while facilitating enhanced gas activation. As another example, the compositions described herein facilitate a range of operating temperatures for a component (such as a pre-heat ring) using a single heating energy source. Benefits also include ease of manufacturing and low costs. For example, large parts can be manufactured out of the compositions at relatively low costs, while achieving the absorption and transmissivity benefits described.

It is contemplated that one or more aspects disclosed herein may be combined. As an example, one or more aspects, features, components, operations and/or properties of the processing chamber 1000, the substrate support 106, the lower liner 311, the upper liner 1020, the pre-heat ring 302, the pre-heat ring 400, the pre-heat ring 600, the method 800, and/or the method 900 may be combined. Moreover, it is contemplated that one or more aspects disclosed herein may include some or all of the aforementioned benefits.

The subject matter described herein (such as the compositions) are described in relation to chamber components (such as semiconductor manufacturing chamber components), the subject matter can be used in other applications. For example, the subject matter can be used in building glass, office glass, and/or automotive glass (such as windows and/or windshields). The subject matter can be used, for example, to block infrared light and/or ultraviolet light while transmitting visible light without a window tint.

While the foregoing is directed to embodiments of the present disclosure, other and further embodiments of the disclosure may be devised without departing from the basic scope thereof, and the scope thereof is determined by the claims that follow.

What is claimed is:

1. A component comprising:
a body having a composition, the composition comprising a mixture of silicon carbide (SiC) particles suspended in quartz.

2. The component of claim 1, wherein the composition has a concentration of the silicon carbide particles that is greater than 1% and less than 5% by volume.

3. The component of claim 2, wherein the concentration of the silicon carbide particles is within a range of 2% to 3% by volume.

4. The component of claim 1, wherein the silicon carbide particles are amorphous.

5. The component of claim 1, wherein the silicon carbide particles have an atomic structure of 4H or 6H.

6. The component of claim 1, wherein the silicon carbide particles have a crystalline structure.

7. The component of claim 1, wherein the body is curved and defines a central opening.

8. The component of claim 1, wherein the component is a pre-heat ring, a liner, or a substrate support for disposition in a processing chamber.

9. The component of claim 1, wherein the quartz is transparent.

10. A processing chamber applicable for use in semiconductor manufacturing, comprising:
a chamber body;
a window, the chamber body and the window at least partially defining a processing volume;
a plurality of heat sources configured to heat the processing volume;
a substrate support disposed in the processing volume;
a liner configured to at least partially line the chamber body; and
a pre-heat ring disposed in the processing chamber and at least partially supported by the liner, the pre-heat ring comprising:
a body having a composition, the composition comprising a mixture of silicon carbide (SiC) particles suspended in quartz.

11. The processing chamber of claim 10, wherein the composition has a concentration of the silicon carbide particles that is greater than 1% and less than 5% by volume.

12. The processing chamber of claim 11, wherein the concentration of the silicon carbide particles is within a range of 2% to 3% by volume.

13. The processing chamber of claim 10, wherein the silicon carbide particles are amorphous.

14. The processing chamber of claim 10, wherein the silicon carbide particles have an atomic structure of 4H or 6H.

15. The processing chamber of claim 10, wherein the silicon carbide particles have a crystalline structure.

16. The processing chamber of claim 10, wherein the liner further comprises:
a body having a composition, the composition comprising a mixture of silicon carbide (SiC) particles suspended in quartz.

17. The processing chamber of claim 10, wherein the substrate support further comprises:
a body having a composition, the composition comprising a mixture of silicon carbide (SiC) particles suspended in quartz.

18. The processing chamber of claim 10, wherein the quartz is transparent.

19. A method of forming a composition comprising:
immersing silicon carbide (SiC) powder in liquid quartz;
mixing the silicon carbide and liquid quartz into a SiC quartz mixture; and
curing the SiC quartz mixture.

20. The method of claim 19, further comprising:
forming the SiC quartz mixture into a pre-heat ring.
